(19) United States
(12) Patent Application Publication
(10) Pub. No.: US 2025/0141178 A1
(43) Pub. Date: May 1, 2025

(54) DEVICE AND METHOD TO CONTROL WARPAGE AND THERMAL DISSIPATION IN AN OPTICAL ENGINE

(71) Applicant: Avago Technologies International Sales Pte. Limited, Singapore (SG)

(72) Inventors: Sukeshwar Kannan, San Jose, CA (US); Sheng Zhang, Cupertino, CA (US); Near Margalit, Westlake Village, CA (US)

(21) Appl. No.: 18/497,630

(22) Filed: Oct. 30, 2023

(51) Int. Cl. H01S 5/0233

(52) U.S. Cl. CPC H01S 5/0233

(57) ABSTRACT

Novel tools and techniques are provided for implementing a semiconductor or optical engine package, and more particularly methods, systems, and apparatuses are provided for implementing a semiconductor package including a dummy die coupled to a top surface of a fan-out wafer comprising an electronic die and coupled to a side of a photonic die. In various embodiments, an apparatus includes a first layer comprising an electronic die. A photonic die can be stacked on and coupled to the electronic die and a dummy die can be coupled to a first side of the photonic die and coupled to the first layer.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to methods, systems, and apparatuses for implementing a semiconductor package or a chip package having an optical engine.

### BACKGROUND

In existing optical engines, a photonic die is often placed beside an electronic die on a substrate. Electrical interconnections are then run through the substrate to electrically connect the photonic die to the electronic die. However, there is a need for shorter die to die interconnections.

Hence, there is a need for more robust and scalable solutions for implementing semiconductor packages and chip packages having optical engines. Thus, methods, systems, and apparatuses are provided for implementing a semiconductor package or a chip package including an optical engine having a photonic die stacked on top of an electronic die and a dummy die located on a side of the photonic die.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIG. 1 is a schematic cross-sectional view of a semiconductor device with a dummy die, in accordance with various embodiments;

FIGS. 2A-2C are schematic cross-sectional views of different embodiments of a semiconductor device with a dummy die, in accordance with various embodiments;

FIG. 3 is a perspective view of a semiconductor device with a dummy die, in accordance with various embodiments;

FIG. 4A-4I are schematic cross-sectional views of a method of manufacturing a semiconductor device with a dummy die, in accordance with various embodiments; and

FIG. 5 is a flow diagram of a method of fabricating a semiconductor device with a dummy, in accordance with various embodiments.

### DETAILED DESCRIPTION OF EMBODIMENTS

Various embodiments provide tools and techniques for implementing semiconductor packages or chip packages including a photonic die stacked on top of an electronic die and a dummy die located on a side of the photonic die are described herein.

In a first aspect, an apparatus comprises a first layer comprising an electronic die, a photonic die disposed on the first layer, and a dummy die disposed on a first side of the photonic die and disposed on the first layer. In some cases, a first length of the photonic die overlapping the first layer is less than a second length of the first layer.

In various embodiments, a first thickness of the photonic die can be about a same thickness as a second thickness of the dummy die. In some instances, the dummy die extends along an entire thickness of the photonic die. The electronic die can be embedded in the first layer.

In some instances, the apparatus further includes an opening between a second side of the dummy die and the first side of the photonic die. The opening can be between about 60 μm to 70 μm. The opening can be filled with a second material. In some cases, the first length of the photonic die, a third length of the dummy die, and a fourth length of the opening combined are about a same length as the second length of the first layer.

In various cases, the first length of the photonic die and a third length of the dummy die combined are about a same length as the second length of the first layer. In some instances, a ratio of the first length of the photonic die to a third length of the dummy die is about 3:1 to about 4:1.

In some embodiments, the dummy die comprises a via extending from a first surface of the dummy die to a second surface of the dummy die. In some cases, the dummy die comprises a connector located at an interface of the first layer and the dummy die. The connector can be configured to couple the dummy die to the first layer.

In various instances, a second material is located between at least one of the dummy die and the photonic die, the dummy die and the first layer, or the photonic die and the first layer.

In another aspect, a method of manufacturing an optical engine can include forming an electronic die; encapsulating the electronic die in a first material; coupling a photonic die to the electronic die encapsulated in the first material; and coupling a dummy die to a first side of the photonic die and to the electronic die encapsulated in the first material. In some cases, a first length of the photonic die overlapping the electronic die encapsulated in the first material is less than a second length of the electronic die encapsulated in the first material.

In some embodiments, before the electronic die is encapsulated in the first material, the method includes coupling the electronic die to a carrier wafer. After coupling the electronic die to the carrier wafer, the electronic die can be encapsulated in the first material.

In various instances, the method further includes, forming the electronic die in a fan-out wafer and, after coupling the photonic die to the electronic die encapsulated in the first material, removing a carrier wafer coupled to the electronic die; and dicing the fan-out wafer to separate the electronic die, the photonic die, and the dummy die from one or more other components formed on the fan-out wafer.

In some cases, the method can further include filling an opening between at least one of the electronic die and the photonic die, the electronic die and the dummy die, or the photonic die and the dummy die with a second material.

In some instances, a first thickness of the photonic die is about a same thickness as a second thickness of the dummy die.

In yet another aspect, an optical engine can include a wafer comprising an electronic die embedded in a layer of the wafer; a photonic die disposed on the electronic die; and a photonic die disposed on the electronic die, wherein a first length of the photonic die overlapping the wafer is less than a second length of the wafer. In some cases, a first length of the photonic die overlapping the wafer is less than a second length of the wafer. In various instances, the first length of the photonic die and a third length of the dummy die combined are about a same length as the second length of the wafer.

In the following description, for the purposes of explanation, numerous details are set forth to provide a thorough understanding of the described embodiments. It will be apparent to one skilled in the art, however, that other embodiments may be practiced without some of these details. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

When an element is referred to herein as being “connected,” “coupled,” “stacked,” or “attached” to another element, it is to be understood that the elements can be directly connected to (or directly stacked on) the other element, or have intervening elements present between the elements. In contrast, when an element is referred to as being “directly connected,” “directly coupled,” “directly stacked,” or “directly attached” to another element, it should be understood that no intervening elements are present in the “direct” connection between the elements. However, the existence of a direct connection does not exclude other connections, in which intervening elements may be present.

When an element is referred to herein as being “disposed” in some manner relative to another element (e.g., disposed on, disposed between, disposed under, disposed adjacent to, or disposed in some other relative manner), it is to be understood that the elements can be directly disposed relative to the other element (e.g., disposed directly on another element), or have intervening elements present between the elements. In contrast, when an element is referred to as being “disposed directly” relative to another element, it should be understood that no intervening elements are present in the “direct” example. However, the existence of a direct disposition does not exclude other examples in which intervening elements may be present.

Likewise, when an element is referred to herein as being a “layer,” it is to be understood that the layer can be a single layer or include multiple layers. For example, a conductive layer may comprise multiple different conductive materials or multiple layers of different conductive materials, and a dielectric layer may comprise multiple dielectric materials or multiple layers of dielectric materials. When a layer is described as being coupled or connected to another layer, it is to be understood that the coupled or connected layers may include intervening elements present between the coupled or connected layers. In contrast, when a layer is referred to as being “directly” connected or coupled to another layer, it should be understood that no intervening elements are present between the layers. However, the existence of directly coupled or connected layers does not exclude other connections in which intervening elements may be present.

Likewise, when an element is referred to herein as being an “electronic circuit” or simply “circuit”, it is commonly recognized as a building block of modern electronics. Circuits are composed of various electronic components such as resistors, capacitors, inductors, diodes, transistors, and integrated circuits. In some cases, integrated circuits can be formed from one or more circuits. These electronic components are carefully selected and interconnected to create a circuit that can perform a specific task or carry out a particular function. Circuits can be as simple as a basic switch that turns a light on and off, or they can be incredibly complex, such as those found in advanced computer systems, communication devices, or medical equipment. Circuits can be categorized into different types based on their purpose or function, including amplifiers, oscillators, filters, power supplies, and logic gates, among others. Additionally, circuits can include software or firmware in addition to hardware or instead of hardware to carry out a particular function.

Additionally, various units, circuits, modules, or other components may be described as “configured to” or “adapted to” perform a task or tasks. In such contexts, “configured to” or “adapted to” is a broad recitation of structure generally meaning “having circuitry that” performs the task or tasks during operation. As such, the unit/circuit/module/component can be configured to perform the task even when the unit/circuit/module/component is not currently on. In general, the circuitry that forms the structure corresponding to “configured to” or “adapted to” may include hardware circuits and/or memory storing program instructions executable to implement the operation. The memory can include volatile memory such as static or dynamic random-access memory and/or nonvolatile memory such as optical or magnetic disk storage, flash memory, programmable read-only memories, etc. Similarly, various unit/circuit/module/component may be described as performing a task or tasks, for convenience in the description. Such descriptions should be interpreted as including the phrase “configured to” or “adapted to.” Reciting a unit/circuit/component that is configured to perform one or more tasks is expressly intended not to invoke 35 U.S.C. § 112, paragraph six interpretation for that unit/circuit/component.

Moreover, the terms left, right, front, back, top, bottom, forward, reverse, clockwise and counterclockwise are used for purposes of explanation only and are not limited to any fixed direction or orientation. Rather, they are used merely to indicate relative locations and/or directions between various parts of an object and/or components.

Furthermore, the methods and processes described herein may be described in a particular order for ease of description. However, it should be understood that, unless the context dictates otherwise, intervening processes may take place before and/or after any portion of the described process, and further various procedures may be reordered, added, and/or omitted in accordance with various embodiments.

Unless otherwise indicated, all numbers used herein to express quantities, dimensions, and so forth should be understood as being modified in all instances by the term “about.” The term “substantially” or “about” used herein refers to variations from the reference value or ratio of ±25% or less (e.g., ±25%, ±20%, ±15%, ±10%, ±5%, etc.), inclusive of the endpoints of the range.

In this application, the use of the singular includes the plural unless specifically stated otherwise, and use of the terms “and” and “or” means “and/or” unless otherwise indicated. Moreover, the use of the terms “including” and “having,” as well as other forms, such as “includes,” “included,” “has,” “have,” and “had,” should be considered non-exclusive. Also, terms such as “element” or “component” encompass both elements and components comprising one unit and elements and components that comprise more than one unit, unless specifically stated otherwise.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items. By way of example, the phrases “at least one of A, B, and C” or “at least one of A, B, or C” each refer to only A, only B, or only C; and/or any combination of A, B, and C. In instances where it is intended that a selection be of “at least one of each of A, B, and C,” or alternatively, “at least one of A, at least one of B, and at least one of C,” it is expressly described as such.

In some existing optical engines, a photonic die is often placed beside an electronic die on a substrate. Electrical interconnections are then run through the substrate to electrically connect the photonic die to the electronic die. However, there is a need for shorter photonic die to electronic die interconnections.

In other existing optical engines, a photonic die is stacked on an electronic die using fan-out wafer level packaging. To build a fanout wafer level package, the electronic die is bumped, thinned, and diced. The electronic die is then coupled to a carrier wafer and encapsulated in an encapsulating material which fans-out from the electronic die. Next, one or more redistribution layers are added to a surface of the electronic die opposite the carrier wafer. Then, the photonic die is coupled to the electronic die encapsulated in the encapsulating material. The photonic die that is coupled to the electronic die is often about a same length as the encapsulating material encapsulating the electronic die in order to mechanically support and reduce warpage of the electronic die and encapsulating material. However, having the photonic die be about a same length as the encapsulating material is expensive and also impacts the yield of the photonic die. In other words, because the photonic die is larger, less photonic dies can be formed on a wafer reducing the yield of the wafer at a wafer processing factory.

The proposed embodiments comprise an optical engine that provides a photonic die stacked on an electronic die encapsulated in an encapsulating material. A length of the photonic die is less than a length of the encapsulating material encapsulating the electronic die. Additionally, a dummy die is provided on a side of the photonic die. A length of the photonic die plus a length of the dummy die are about a same length as the encapsulating material encapsulating the electronic die.

Several advantages can be achieved by providing a dummy die. First, the yield of photonic die can be larger than when the photonic die is a same length as the encapsulating material. In other words, because the photonic die is smaller, more photonic dies can be formed on a wafer increasing a yield of the wafer at a wafer processing factory. Additionally, the photonic die and the dummy die together can mechanically support and reduce warpage of the electronic die and encapsulating material. Further, the dummy die can dissipate heat from the electronic die.

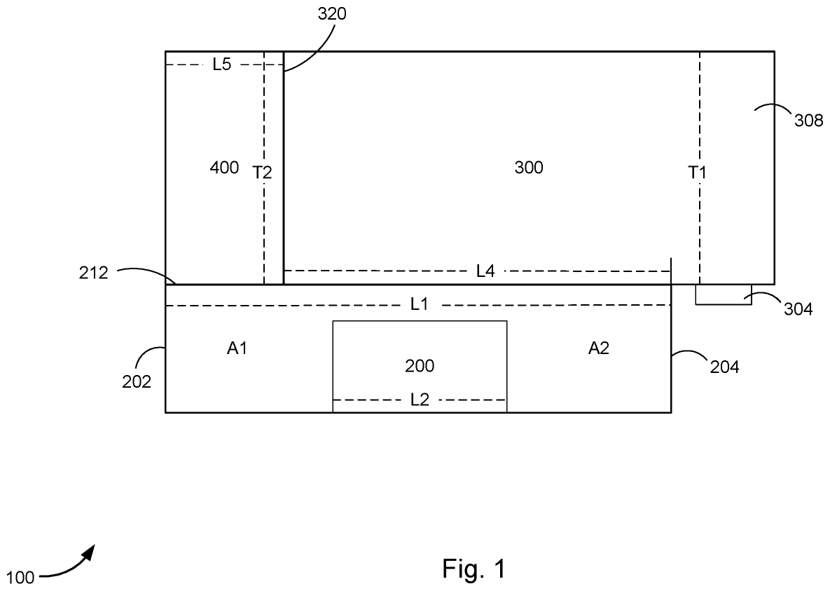

FIGS. 1-3 are views of different embodiments of a semiconductor device or optical engine 100, in accordance with various embodiments. It should be noted that the various components of semiconductor device 100 are schematically illustrated in FIGS. 1-3, and that modifications to the various components, orientations, and other arrangements of semiconductor device 100 may be possible and in accordance with the various embodiments. In addition, only some components and/or layers of the semiconductor device 100 are shown in FIGS. 1-3, there could be more or less components and/or layers, in accordance with various embodiments and semiconductor device 100 is not intended to be limited to only the components and/or layers shown. In addition, although FIGS. 1-3 are described as separate embodiments for ease of description, a person of ordinary skill would understand that various modifications to each embodiment may be applied to other embodiments.

In various embodiments, the semiconductor device 100 includes an electronic die 200, a photonic die 300, and a dummy die 400.

In some cases, the electronic die or electronic integrated circuit 200 can include one or more layers (not shown). The one or more layers can include, without limitation, one or more dielectric layers, one or more device or circuit layers, one or more conducting layers, one or more insulating layers, one or more redistribution layers, other layers, and/or the like. The layers may further include one or more layers configured to provide component interconnections. In a non-limiting example, connections may be routed, for example, through the electronic die 200 via one or more interconnects. In some instances, the electronic die is formed from one or more of silicon, silicon germanium, and/or other material or combination of materials.

In some embodiments, the electronic die 200 can act as a central processing unit, which includes one or more controlling circuits. The one or more controlling circuits of the electronic die 200 can be configured to control one or more operations of the photonic die 300, one or more devices in the photonic die 300, and/or other dies or devices (e.g., a switch die, a digital signal processor die, and/or other dies) disposed within semiconductor device 100. The electronic die 200 can also be configured to transmit electrical signals to or receive electrical signals from the photonic die 300 and/or other dies or devices disposed within semiconductor device 100. In addition, the electronic die 200 can include one or more circuits for processing one or more electrical signals that have been converted from one or more optical signals in the photonic die 300.

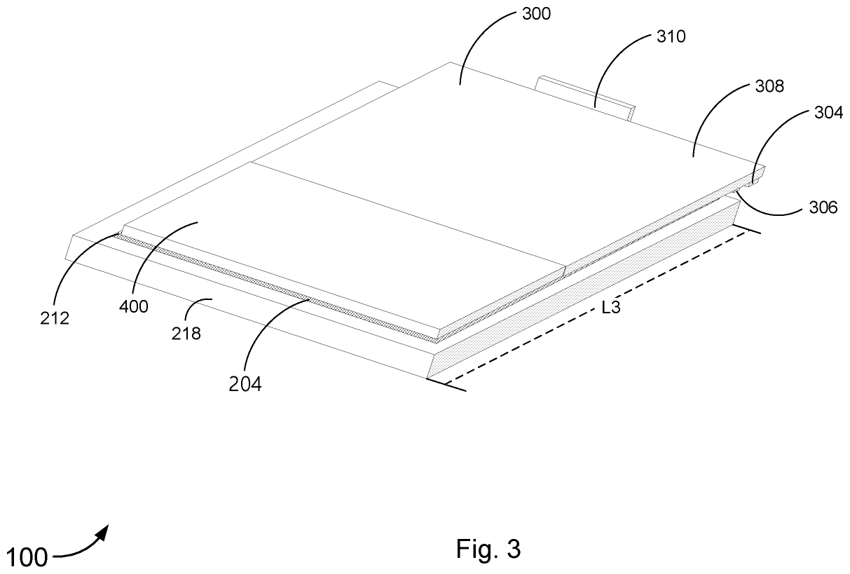

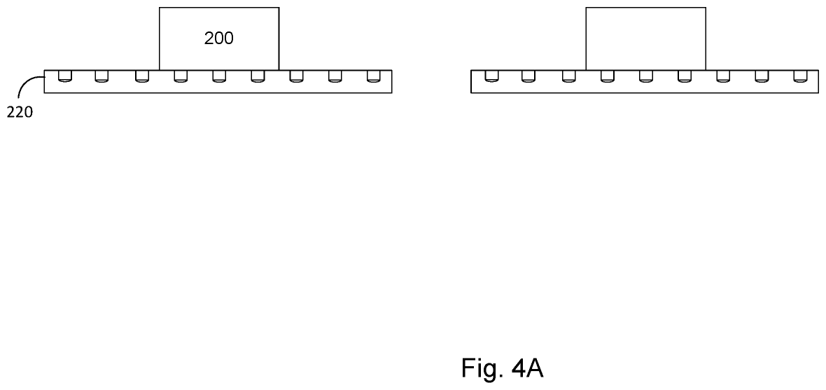

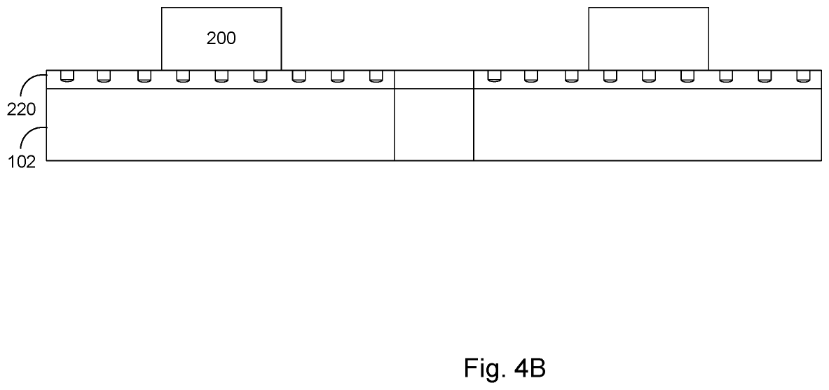

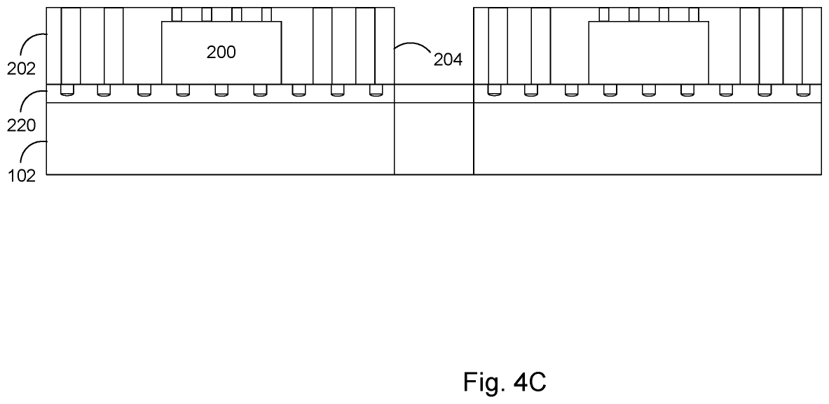

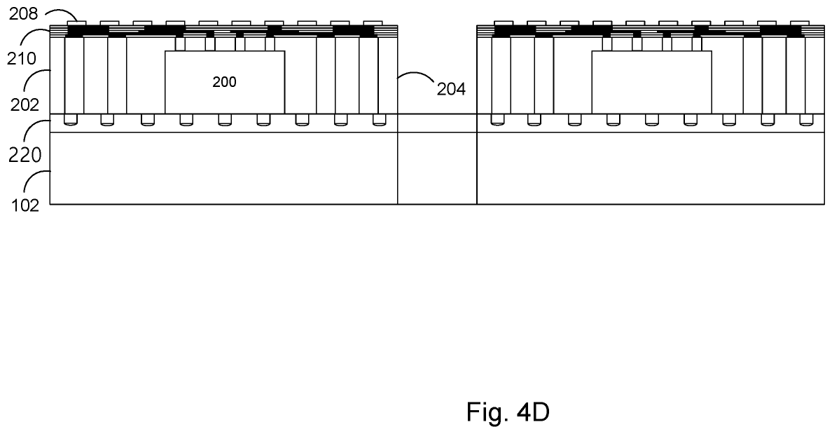

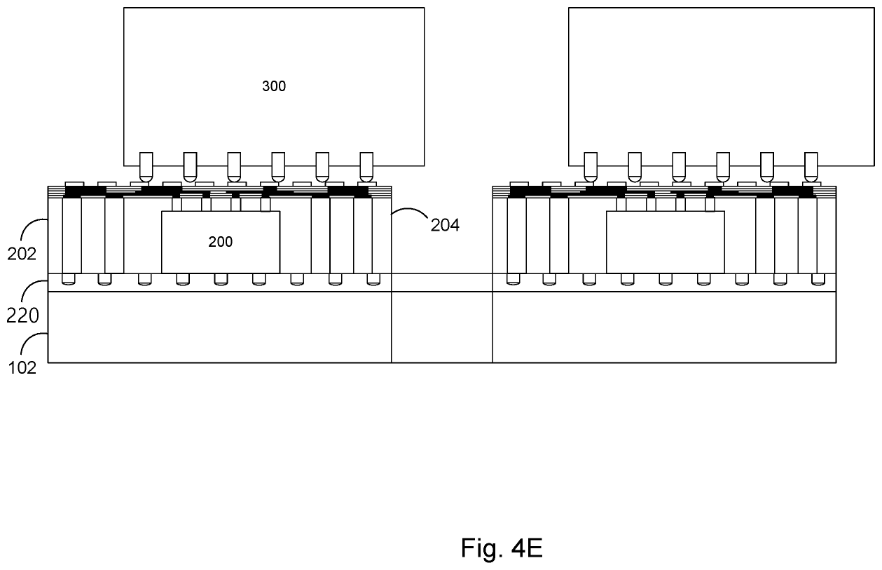

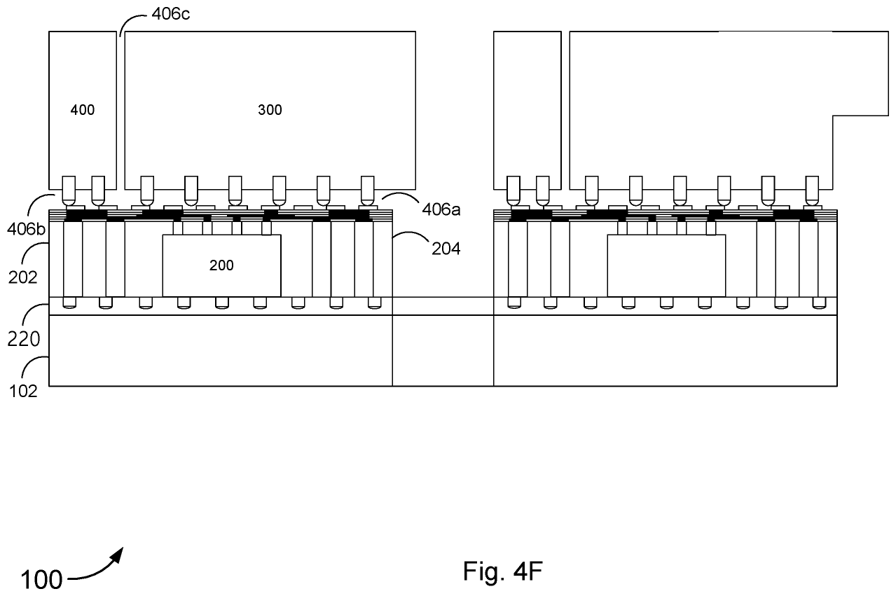

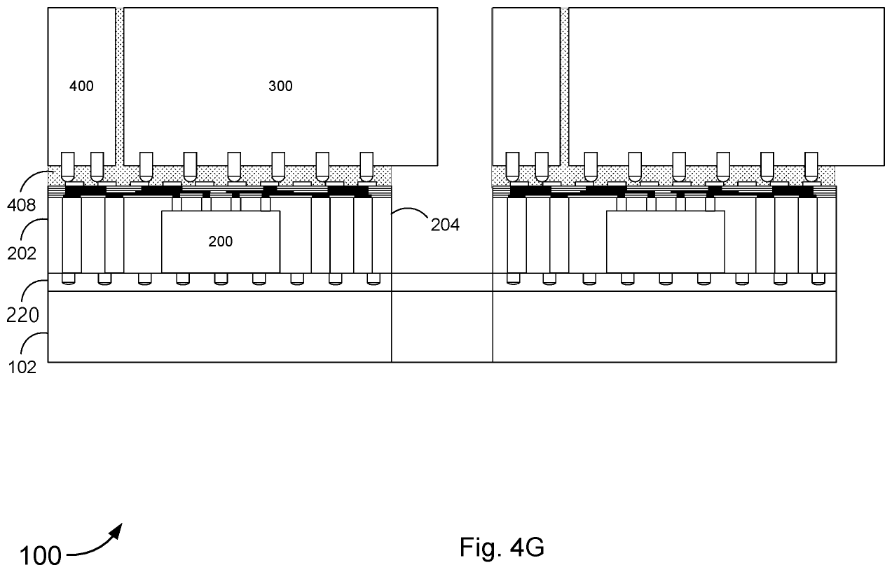

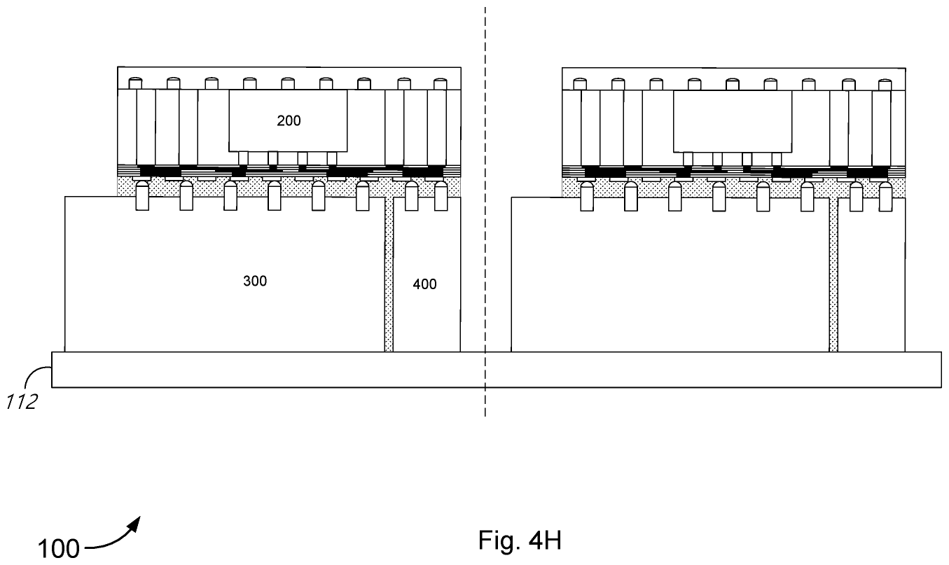

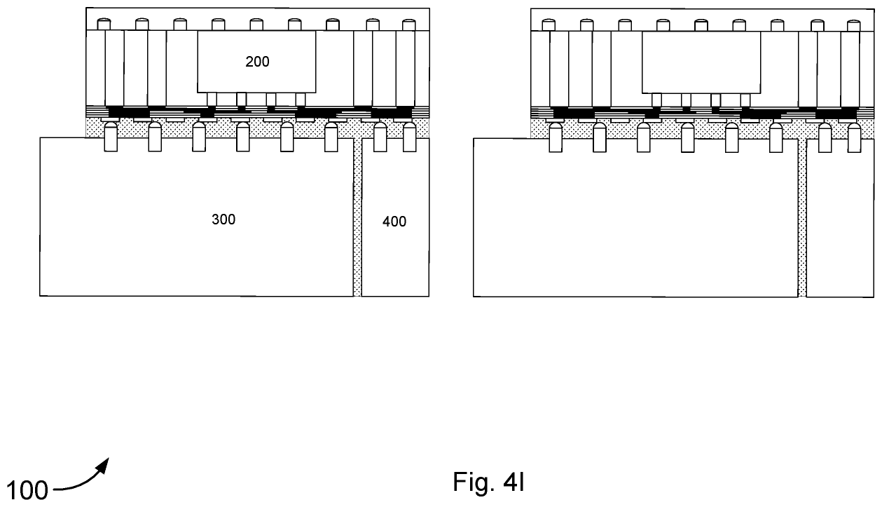

In some cases, the electronic die 200 can be formed using a fan-out wafer packaging process described below with respect to FIGS. 3 and 4. When the electronic die is formed using a fan-out wafer packaging process, the electronic die 200 can be encapsulated or embedded in an encapsulating material or encapsulating material layer 202. The encapsulating material 202 can include, without limitation, epoxy, epoxy compound, mold, mold compound, resin, resin compound, and/or the like, or other material configured to encapsulate or embed the electronic die 200.

When the electronic die 200 is embedded in an encapsulating material 202, the encapsulating material can fan-out or spread-out from the electronic die 200 and form a fan-out area (e.g., areas A1 and A2). In other words, when the electronic die 200 is encapsulated in the encapsulating material 202, a length L2 of the electronic die 200 is less than a length L1 of the encapsulating material 202 which fans out around the electronic die 200 (shown in FIG. 1). In some embodiments, the encapsulating material 202 and the electronic die 200 can form a fan-out wafer or layer 204. In various instances, the length of the fan-out wafer 204 is the length L1 of the encapsulating material 202. In various instances, a length L1 and/or a size of the fan-out wafer 204 is about 1.3 to 1.5 times longer or larger than a length L2 or size of the electronic die 200.

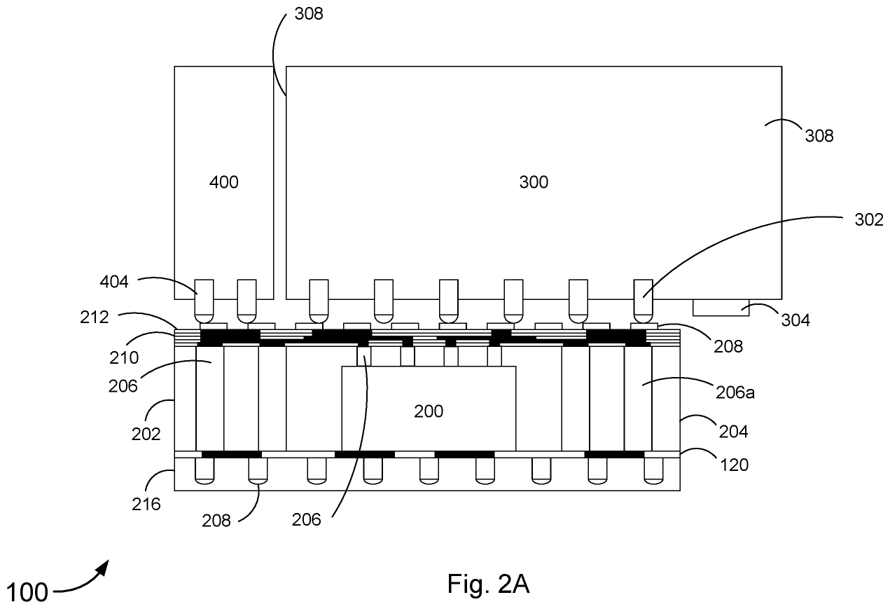

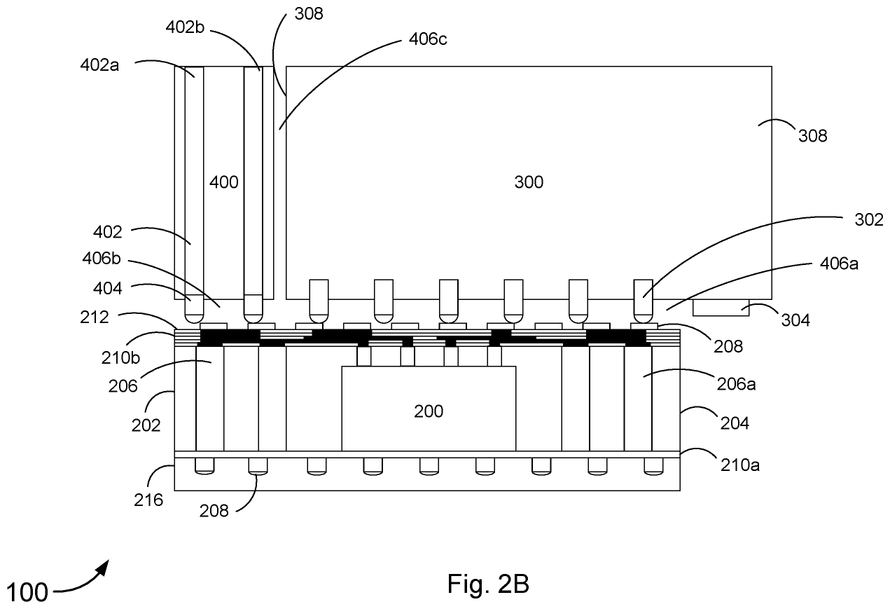

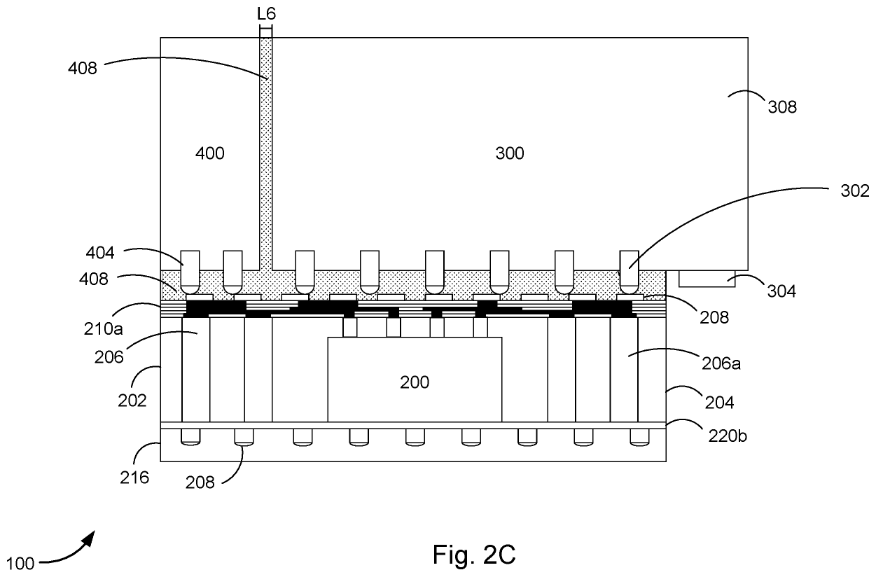

In some cases, the fan out wafer 204 can further include one or more layers. The one or more layers can include, without limitation, one or more dielectric layers, one or more device layers, one or more conducting layers, one or more insulating layers, one or more redistribution layers, other layers, and/or the like. The layers may further include one or more layers configured to provide component interconnections. In a non-limiting example, connections may be routed, for example, through the fan-out wafer 204 via one or more interconnects 206 (shown in FIG. 2A-2C). The one or more interconnects 206 of the fan-out wafer 204 may be configured to connect (e.g., electrically connect) to one or more connectors 208 which are configured to connect to a circuit board, a packaging substrate 218, photonic die 300 and/or dummy die 400.

The interconnects 206 and/or connectors 208 can be one or more structures that couple (e.g., electrically couple or the like) two or more elements (e.g., a circuit board, a packaging substrate 218, electronic die 200, photonic die 300, dummy die 400, or the like) of the semiconductor device 100 together. The interconnects 206 and/or connectors 208 may include one or more pads, traces, vias, micro bumps, solder balls, posts or pillars, and/or other suitable interconnects or connectors. The one or more vias may extend completely through fan-out wafer 204 (e.g., a “through” via), may extend through a portion of the fan-out wafer 204 from one outer surface (e.g., a “blind” via), or may extend through a portion of the fan-out wafer 204 and be completely hidden from external view (e.g., a “buried” via), and/or the like. The one or more interconnects 206 and/or connectors 208 can comprise an electrically conductive material such as copper, aluminum, titanium, gold, silver, tin, nickel, lead, or a combination of metals/alloys, or may be formed of other electrically conductive material or combination of electrically conductive materials. In some cases, the one or more interconnects 206 can include one or more through-vias 206a (shown in FIG. 2A) configured to surround electronic die 200. The one or more through-vias 206a can be configured to deliver power or other electrical signals directly to photonic die 300.

In various embodiments, the fan-out wafer 204 might further include one or more redistribution layers 210 (shown in FIGS. 2A-2C) which are provided within the fan-out wafer 204. Alternatively, the one or more redistribution layers 210 can be formed on top or bottom of and coupled to the fan-out wafer 204 as separate layers. In some cases, one or more redistribution layers 210a can be formed on a top surface 212 of the fan-out wafer 204 while one or more redistribution layers 210b can be formed on a bottom surface 214 of the fan-out wafer 204. The one or more redistribution layers 210 can be configured to route one or more connections (e.g., electrical connections or the like) to desired locations (e.g., from or to a packaging substrate 218, the electronic die 200, through-vias 206a, interconnects 206, connectors 208, photonic die 300, vias, interconnects, and/or the like). In some cases, the one or more redistribution layers 210 can be configured to deliver electrical signals via the one or more connections.

In some instances, an underfill layer 216 (shown in FIGS. 2A-2C) can be disposed between the one or more redistribution layers 210b and a packaging substrate 218 (shown in FIG. 3). The underfill layer 216 can be configured to surround the one or more connectors 208 between the one or more redistribution layers 210b and the packaging substrate 218 and adhere the one or more redistribution layers 210b to the packaging substrate 218. In some cases, the under layer 216 can protect the one or more connectors 208 during the fabrication process of semiconductor device 100. The underfill layer 216 can be formed from one or more of an epoxy, epoxy compound, mold, mold compound, resin, resin compound, and/or the like. The packaging substrate 218 can be formed from one or more of an organic compound, and/or the like. In some cases, a length L3 of the packaging substrate 218 about a same length or a greater length than a length L1 of the fan-out wafer 204. In some cases, packaging substrate 218 is configured to connect to a circuit board (not shown).

In some instances, the fan-out wafer 204 and/or one or more redistribution layers 210a can be coupled to a photonic die or photonic integrated circuit (PIC) 300. In some cases, the photonic die 300 is configured to couple to or be disposed on a top surface 212 of the fan-out wafer 204. In some instances, the photonic die 300 is formed from one or more of silicon, silicon nitride, indium phosphide, silicon on insulator (SOI), and/or the like. The photonic die 300 can include one or more layers (not shown). The one or more layers can include, without limitation, one or more dielectric layers, one or more device or circuit layers, one or more conducting layers, one or more insulating layers, one or more redistribution layers, other layers, and/or the like.

The layers may further include one or more layers configured to provide component interconnections. In a non-limiting example, connections may be routed, for example, through the photonic die 300 via one or more interconnects (not shown). The one or more interconnects of the photonic die may be configured to provide one or more connections (e.g., electrical connections, optical connections, and/or the like). In some cases, the photonic die 300 might further include one or more connectors 302 (shown in FIGS. 2A-2C). The connectors 302 can be one or more structures that couple (e.g., electrically couple or the like) two or more elements (e.g., electronic die 200, photonic die 300, through-vias 206a, or the like) of the semiconductor device 100 together.

The interconnects and/or connectors 302 may include one or more pads, traces, vias, micro bumps, solder balls, posts or pillars, and/or other suitable interconnects or connectors. The one or more vias may extend completely through a photonic die 300 (e.g., a “through” via), may extend through a portion of the photonic die 300 from one outer surface (e.g., a “blind” via), or may extend through a portion of the photonic die 300 and be completely hidden from external view (e.g., a “buried” via), and/or the like. The one or more interconnects and/or connectors 302 can comprise an electrically conductive material such as copper, aluminum, titanium, gold, silver, tin, nickel, lead, or a combination of metals/alloys, or may be formed of other electrically conductive material or combination of electrically conductive materials.

The photonic die 300 can be configured to be optically coupled to one or more optical signal sources such as optical fibers, photo diodes, light sources, or laser dies, or the like. The photonic die 300 can have one or more circuits configured to receive, transmit, or convert one or more optical signals from the optical signal source (e.g., light source 304 shown in FIGS. 2A-2C and FIG. 3 and described below). The photonic die 300 can be configured to receive one or more optical signals from the one or more optical signal sources, transmit the one or more optical signals inside the photonic die 300, transmit the one or more optical signals out of the photonic die 300, and/or the like. In some cases, the photonic die 300 can be configured to convert the one or more optical signals received from the one or more optical signal sources to one or more electrical signals and communicate the one or more electrical signals to the electronic die 200. In some cases, the photonic die 300 is configured to receive one or more electrical signals from the electronic die 200 (e.g., to control the one or more optical sources, or the like).

In some cases, the photonic die 300 comprises a light source or a light source diode 304 and a lens 306 (shown in FIG. 3) configured to direct, focus, bend, or the like the light from the light source 304. The light source 312 can be a laser and/or any other source configured to generate light. In various cases, a portion 308 of the photonic die comprising the light source 304 and the lens 306 hangs over the fanout wafer 204. In some cases, the photonic die 300 can further include an input or output lens 310 (shown in FIG. 3). The input or output lens 310 can be configured to output light from the light source 304 and/or receive input from light source 304 or another light source (not shown). The photonic die 300 can be configured to receive one or more optical signals from the light source 304 or another light source, transmit the one or more optical signals from the light source 304 or another light source inside the photonic die 300, transmit the one or more optical signals from the light source 304 or another light source out of the photonic die 300 (e.g., to electronic die 200, to another photonic die), convert the one or more optical signals from the light source 304 or another light source to one or more electrical signals and transmit the one or more electrical signals out of the photonic die (e.g., to electronic die), and/or the like.

In various embodiments, the semiconductor device 100 further includes a dummy die 400. The dummy die 400 is configured to attach to or be disposed on a side 320 of the photonic die 300 and a top surface 212 of the electronic die 200. The dummy die 400 can be formed from one or more of silicon, polycrystalline silicon, and/or the like. The dummy die 400 can include one or more layers (not shown). The one or more layers can include, without limitation, one or more dielectric layers, one or more device or circuit layers, one or more conducting layers, one or more insulating layers, one or more redistribution layers, other layers, and/or the like.

The layers may further include one or more layers configured to provide component interconnections. In a non-limiting example, connections may be routed, for example, through the dummy die 400 via one or more interconnects 402 (shown in FIG. 2C). The one or more interconnects of the dummy die 400 may be configured to provide one or more connections (e.g., electrical connections, thermodynamic connections, and/or the like). In some cases, the dummy die 400 might further include one or more connectors 404 (shown in FIGS. 2A-2C).

The interconnects 402 and/or connectors 404 can be one or more structures that couple (e.g., electrically couple, thermodynamically couple, or the like) two or more elements (e.g., dummy die 400, electronic die 200, photonic die 300, or the like) of the semiconductor device 100 together. The interconnects 402 and/or connectors 404 may include one or more pads, traces, vias, micro bumps, solder balls, posts or pillars, and/or other suitable interconnects or connectors. The one or more vias may extend completely through dummy die 400 (e.g., a “through” via), may extend through a portion of the dummy die 400 from one outer surface (e.g., a “blind” via), or may extend through a portion of the dummy die 400 and be completely hidden from external view (e.g., a “buried” via), and/or the like. The one or more interconnects 402 and/or connectors 404 can comprise an electrically conductive material such as copper, aluminum, titanium, gold, silver, tin, nickel, lead, or a combination of metals/alloys, or may be formed of other electrically conductive material or combination of electrically conductive materials.

In some cases, the one or more interconnects 402 might include one or more through-vias 402a and 402b (shown in FIG. 2B). The one or more through vias 402a and 402b might be configured to dissipate heat from a circuit board, packaging substrate 218, electronic die 200, fan-out wafer 204, photonic die 300, and/or the like. Alternatively, in other cases, the dummy die 400 itself can be configured to dissipate heat from a circuit board, electronic die 200, fan-out wafer 204, photonic die 300, and/or the like.

In various cases, a thickness T1 of the photonic die 300 is about a same thickness T2 as the dummy die 400. In some cases, a length L4 (e.g., a length of the photonic die 300 on top of the fan-out wafer 204 and excluding a length of the portion of the photonic die 300 overhanging the fan-out wafer 204) of a portion of the photonic die 300 plus a length L5 of the dummy die 400 can be about a same length as the length L1 of the fan-out wafer 204. In various cases, a ratio of a length L4 of the photonic die 300 to a length L5 of the dummy die 400 is about 3:1 to about 4:1.

By having the thickness T1 of the photonic die be about a same thickness T2 as the dummy die 400 and/or by having a length L4 of a portion of the photonic die 300 plus a length L5 of the dummy die 400 be about a same length as the length L1 of the fan-out wafer 204, the photonic die 300 and the dummy die 400 can be configured to support the fan-out wafer 204 comprising the electronic die 200. In other words, the photonic die 300 and the dummy die 400 can provide structural rigidity to the fan-out wafer 204 comprising the electronic die 200 and control, restrain, or prevent the deformation or warpage of the fan-out wafer 204. In some cases, the photonic die 300 and the dummy die 400 together control or prevent in-plane thermal expansion or contraction along length L1 of the fan-out wafer 204. Additionally, in order to restrain the fan-out wafer 204, the photonic die 300 and the dummy die 400 together control or prevent out-of-plane (with respect to a plane extending along a length of the substrate) rotation of the fan-out wafer 204. In other words, the photonic die 300 and the dummy die 400 together control or prevent the fan-out wafer 204 from curving or curling out-of-plane with respect to a plane extending along a length L1 of the fan-out wafer.

Warpage or deformation of the fan-out wafer 204 may occur due to due to different construction materials used for the fan-out wafer 204, due to a coefficient of thermal expansion mismatch between the packaging substrate 218 and the fan-out wafer 204, due to the deposition of one or more redistribution layers 210, or the like. A semiconductor device that has warped or deformed more than a predetermined amount may be rendered useless because one or more interconnects (e.g., interconnects 110, 206, 402 or the like) or connectors (e.g., connectors 115, 208, 302, 404, or the like) cannot connect to one or more other interconnects (e.g., interconnects 110, 206, 402 or the like) or connectors (e.g., connectors 115, 208, 302, 404, or the like). The photonic die 300 together with the dummy die 400 works to restrain, prevent, or control the fan-out wafer 204 from warping more than the predetermined amount and ensure that one or more interconnects (e.g., interconnects 110, 206, 402 or the like) or connectors (e.g., connectors 115, 208, 302, 404, or the like) can connect to one or more other interconnects (e.g., interconnects 110, 206, 402 or the like) or connectors (e.g., connectors 115, 208, 302, 404, or the like).

In various instances, one or more openings 406a, 406b, and 406c (shown in FIG. 2B) between one or more of the fan-out wafer 204, the photonic die 300, and/or the dummy die 400 can be filled with an underfill material 408 (shown by the dotted area in FIG. 2C). The underfill material 408 can include, without limitation, an epoxy, a resin, and/or any other material capable of filling openings 406a-406c. The underfill material 408 can be injected into the one or more openings 406a-406c. In some cases, the underfill material 408 can further be configured to support the fan-out wafer 204.

In some cases, a length L6 (shown in FIG. 2C) of the opening 406c between the photonic die 300 and the dummy die 400 is about 60 μm to about 70 μm or less. The opening 406c can be filled with the underfill material 408. By filling the opening 406a between the photonic die 300 and the fan-out wafer 204, the opening 406b between the fan-out wafer 204 and the dummy die 400, and the opening 406c between the photonic die 300 and the dummy die 400 with the underfill material 408, the photonic die 300 and the dummy die 400 can be bonded or adhered together and act as a larger top die on top of the fan-out wafer 204. By having the photonic die 300 and the dummy die 400 act as a larger top die, the photonic die 300 and the dummy die 400 together can control or prevent the deformation or warpage of the fan-out wafer 204 as described above.

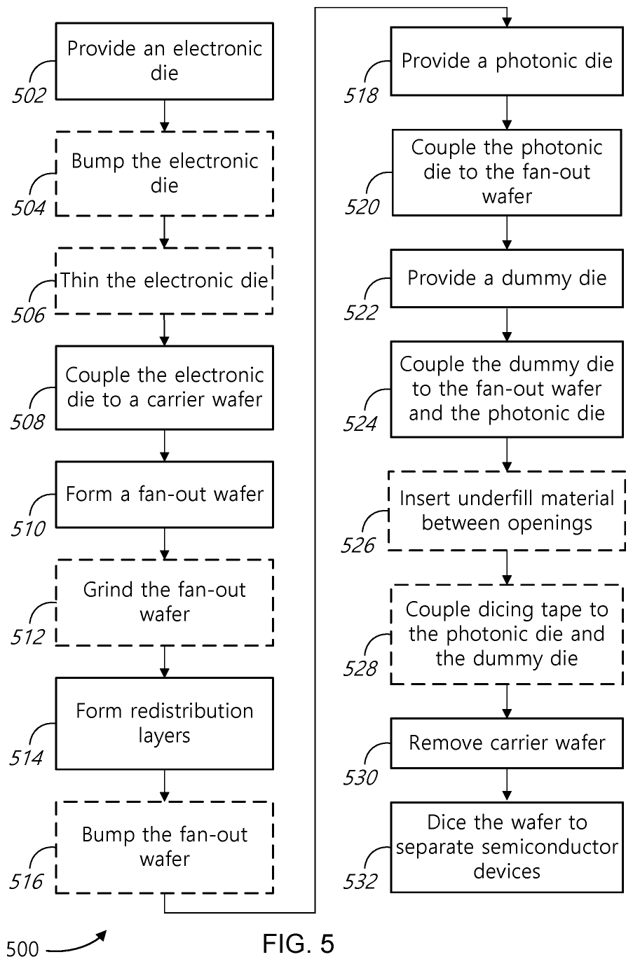

FIG. 5 is a flow diagram of a method 500 of manufacturing a semiconductor device or optical engine (e.g., semiconductor device or optical engine 100), in accordance with various embodiments. FIG. 5 is one example of how to form a semiconductor device or optical engine. However, a person of ordinary skill in the art would understand that a semiconductor device or optical engine can be formed using different methods as well.

FIGS. 4A-4I represent the steps of the method of manufacturing a semiconductor device or optical engine (e.g., semiconductor device or optical engine 100) of FIG. 5. It should be noted that the various components of FIGS. 4A-4I are schematically illustrated, and that modifications to the various components, orientations, and other arrangements of FIG. 4 may be possible and in accordance with the various embodiments. In addition, only some components and/or layers of the device are shown in FIGS. 4A-4I, there could be more or less components and/or layers, in accordance with various embodiments and the device of FIGS. 4A-4I is not intended to be limited to only the components and/or layers shown.

Turning to FIG. 4A and FIG. 5, the method 500 can begin, at block 502, by forming or providing an electronic die (e.g., electronic die 200 or the like). The electronic die can be formed using one or more photolithography processes, patterning processes, etching processes, deposition processes, doping processes, and/or the like. The processes can be used to form one or more circuits to perform one or more functions (e.g., controlling one or more operations of a photonic die, transmitting one or more electrical signals to or receiving one or more electrical signals from the photonic die, processing one or more electrical signals that have been converted from one or more optical signals by the photonic die, and/or other functions). In various cases, the electronic die can be formed as part of a wafer, which includes a plurality of electronic dies arranged as an array. The electronic die can then be diced into a plurality of separated electronic dies.

Next, the method 500, at block 504 can optionally include bumping (e.g., coupling one or more connectors) to the electronic die. Next, the electronic die can be optionally thinned at optional block 506. Finally, the electronic die can be coupled to a carrier wafer (e.g., carrier wafer 102) at block 508 and FIG. 4B. In some cases, a glue or adhesive layer (e.g., glue layer 220) can be formed between the carrier wafer and the electronic die to protect one or more connectors between the carrier wafer and the electronic die. As an example, the term “carrier” or “support” refers to a material or layer that holds, supports, protects, and/or provides structural and mechanical rigidity to the fan-out wafer (e.g., fan-out wafer 204) and the electronic die (e.g., electronic die 200). There are different types of carrier or support substrates depending on the packaging technology and application. For example, a carrier according to embodiments of the present disclosure may include one or more materials such as monocrystalline silicon, polycrystalline silicon, gallium arsenide, sapphire, silicon carbide, glass material, organic material, ceramic material, and/or other material configured to carry or support the substrate and the electronic die during the fabrication process. Multiple electronic dies can be coupled to the carrier wafer and arranged as an array or electronic dies on the carrier wafer.

Once coupled to the carrier wafer, the fan-out wafer (e.g., fan-out wafer 204) can be formed, at block 510 and FIG. 4C, by encapsulating, embedding, or molding the electronic die in a first material (e.g., first material 202). The first material might include an epoxy compound, and/or the like. The fan-out wafer can then go through an optional grinding process at optional block 512. In some cases, one or more interconnects (e.g., interconnects 206) can be formed within fan-out wafer before or after the first material is deposited on the electronic die.

Once the fan-out wafer is formed, the method can continue, at block 514 and FIG. 4D, by forming one or more redistribution layers (e.g., redistribution layers 210) on the fan-out wafer. The method 500, at optional block 516, can include bumping (e.g., coupling one or more connectors (e.g., connectors 208)) to the one or more redistribution layers.

The method 500, at block 518, can then include providing or forming a photonic die (e.g., photonic die 300 or the like). In some cases, the photonic die can be formed in parallel with (e.g., at the same time as) the electronic die and/or fan-out wafer. In some cases, the photonic die can be formed at a different location or at a different time than the electronic die and/or fan-out wafer. The photonic die can be formed using one or more photolithography processes, patterning processes, etching processes, deposition processes, doping processes, and/or the like. The processes can be used to form one or more circuits to perform one or more functions (e.g., controlling one or more operations of a light source (e.g., light source or the like), transmitting one or more electrical signals to or receiving one or more optical signals from the light source, converting one or more optical signals to one or more electrical signals, transmitting one or more electrical to or receiving one or more electrical signals from the electronic die, and/or other functions). In various cases, the photonic die can be formed as part of a wafer, which includes a plurality of dummy dies arranged as an array. The photonic die can then be diced into a plurality of separated photonic dies.

Next, in some embodiments, the method 500 can include, at block 520 and FIG. 4E, coupling the photonic die to the fan-out wafer comprising the electronic die. In some cases, one or more connectors or interconnects (e.g., interconnects 206, connectors 208, or the like) of the fan-out wafer can be coupled to or bonded to one or more connectors or interconnects (e.g., connectors 302 or the like) of the photonic die.

The method 500 can further continue at block 522 by providing or forming a dummy die (e.g., dummy die 400 or the like). The dummy die can be formed in parallel with (e.g., at the same time as) the electronic die, fan-out wafer, and/or photonic die. In some cases, the dummy die can be formed at a different location or at a different time than the electronic die, fan-out wafer, and/or photonic die. The dummy die can be formed using one or more photolithography processes, patterning processes, etching processes, deposition processes, doping processes, and/or the like. The processes can be used to form one or more circuits to perform one or more functions (e.g., transmitting or receiving one or more electrical signals, and/or other functions) or to form one or more heat dissipation structures (e.g., one or more through-vias, and/or other structures configured to dissipate heat. In various cases, the dummy die can be formed as part of a wafer, which includes a plurality of dummy dies arranged as an array. The dummy die can then be diced into a plurality of separated dummy dies.

In some embodiments, the method 500 can include, at block 524 and FIG. 4F, coupling the dummy die to the fan-out wafer comprising the electronic die and the photonic die. In some cases, one or more connectors or interconnects (e.g., interconnects 206, connectors 208, or the like) of the fan-out wafer can be coupled to or bonded to one or more connectors or interconnects (e.g., interconnects 402, connectors 404, or the like) of the dummy die. In various cases, the dummy die is coupled to a side of the photonic die such that the dummy die and the photonic die together act as one larger wafer or die on top of the fan-out wafer comprising the electronic die.

Once the electronic die, photonic die, and dummy die are coupled together, the method 500 can continue, at optional block 526 and FIG. 4G, by injecting or inserting underfill material (e.g., underfill material 408) into one or more openings (e.g., openings 406a-406c) formed between one or more of the electronic die, photonic die, and/or dummy die. The underfill material can be configured to adhere or couple the photonic die and dummy die together such that the dummy die and the photonic die together act as one larger wafer on top of the fan-out wafer comprising the electronic die.

Next the method 500 can continue, at optional block 528 and FIG. 4H, by attaching dicing tape (e.g., dicing tape 112) to a surface of the photonic die opposite the fan-out wafer and removing at block 530 the carrier wafer. Once the dicing tape is added and the carrier wafer is removed, an array of semiconductor devices comprising the fan-out wafer, the electronic die, the photonic die, and the dummy die can be diced, at block 532 and FIG. 4I, to separate the semiconductor devices from one another.

The techniques and processes described above with respect to various embodiments may be used to manufacture the semiconductor devices 100 of FIGS. 1-4, and/or components thereof, as described herein.

While some features and aspects have been described with respect to the embodiments, one skilled in the art will recognize that numerous modifications are possible. For example, the methods and processes described herein may be implemented using hardware components, custom integrated circuits (ICs), programmable logic, and/or any combination thereof. Further, while various methods and processes described herein may be described with respect to particular structural and/or functional components for ease of description, methods provided by various embodiments are not limited to any particular structural and/or functional architecture but instead can be implemented in any suitable hardware configuration. Similarly, while some functionality is ascribed to one or more system components, unless the context dictates otherwise, this functionality can be distributed among various other system components in accordance with the several embodiments.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with or without some features for ease of description and to illustrate aspects of those embodiments, the various components and/or features described herein with respect to a particular embodiment can be substituted, added and/or subtracted from among other described embodiments, unless the context dictates otherwise. Consequently, although several embodiments are described above, it will be appreciated that the invention is intended to cover all modifications and equivalents within the scope of the following claims.

What is claimed is:

1. An apparatus comprising:
a first layer comprising an electronic die;
a photonic die disposed on the first layer, wherein a first length of the photonic die overlapping the first layer is less than a second length of the first layer; and
a dummy die disposed on a first side of the photonic die and disposed on the first layer.

2. The apparatus of claim 1, wherein a first thickness of the photonic die is about a same thickness as a second thickness of the dummy die.

3. The apparatus of claim 1, wherein the dummy die extends along an entire thickness of the photonic die.

4. The apparatus of claim 1, wherein the electronic die is embedded in the first layer.

5. The apparatus of claim 1, further comprising an opening between a second side of the dummy die and the first side of the photonic die, wherein the opening is between about 60 μm to about 70 μm.

6. The apparatus of claim 1, further comprising an opening between a second side of the dummy die and the first side of the photonic die, wherein the opening is filled with a second material.

7. The apparatus of claim 6, wherein the first length of the photonic die, a third length of the dummy die, and a fourth length of the opening combined are about a same length as the second length of the first layer.

8. The apparatus of claim 1, wherein the first length of the photonic die and a third length of the dummy die combined are about a same length as the second length of the first layer.

9. The apparatus of claim 1, wherein a ratio of the first length of the photonic die to a third length of the dummy die is about 3:1 to about 4:1.

10. The apparatus of claim 1, wherein the dummy die comprises a via extending from a first surface of the dummy die to a second surface of the dummy die.

11. The apparatus of claim 1, wherein the dummy die comprises a connector located at an interface of the first layer and the dummy die, wherein the connector is configured to couple the dummy die to the first layer.

12. The apparatus of claim 1, wherein a second material is located between at least one of the dummy die and the photonic die, the dummy die and the first layer, or the photonic die and the first layer.

13. A method of manufacturing an optical engine, the method comprising:
forming an electronic die;
encapsulating the electronic die in a first material;
coupling a photonic die to the electronic die encapsulated in the first material, wherein a first length of the photonic die overlapping the electronic die encapsulated in the first material is less than a second length of the electronic die encapsulated in the first material; and
coupling a dummy die to a first side of the photonic die and to the electronic die encapsulated in the first material.

14. The method of claim 13, wherein, before the electronic die is encapsulated in the first material, the method includes coupling the electronic die to a carrier wafer.

15. The method of claim 14, wherein, after coupling the electronic die to the carrier wafer, the electronic die is encapsulated in the first material.

16. The method of claim 13, wherein, the electronic die is formed in a fan-out wafer, and wherein, after coupling the photonic die to the electronic die encapsulated in the first material, the method further comprises:
removing a carrier wafer coupled to the electronic die; and
dicing the fan-out wafer to separate the electronic die, the photonic die, and the dummy die from one or more other components formed on the fan-out wafer.

17. The method of claim 13, wherein the method further comprises filling an opening between at least one of the electronic die and the photonic die, the electronic die and the dummy die, or the photonic die and the dummy die with a second material.

18. The method of claim 13, wherein a first thickness of the photonic die is about a same thickness as a second thickness of the dummy die.

19. An optical engine comprising:
a wafer comprising an electronic die embedded in a layer of the wafer;
a photonic die disposed on the electronic die, wherein a first length of the photonic die overlapping the wafer is less than a second length of the wafer; and
a dummy die disposed on a first side of the photonic die and disposed on the wafer.

20. The optical engine of claim 19, wherein the first length of the photonic die and a third length of the dummy die combined are about a same length as the second length of the wafer.
